(19) United States
(12) Patent Application Publication
(10) Pub. No.: US 2015/0087140 A1
(43) Pub. Date: Mar. 26, 2015

(54) FILM FORMING METHOD, FILM FORMING DEVICE, AND FILM FORMING SYSTEM

(71) Applicant: TOKYO ELECTRON LIMITED, Tokyo (JP)

(72) Inventors: Toshihisa Nozawa, Miyagi (JP); Hirokazu Ueda, Yamanashi (JP)

(73) Assignee: TOKYO ELECTRON LIMITED, Tokyo (JP)

(21) Appl. No.: 14/395,690

(22) PCT Filed: Apr. 22, 2013
(86) PCT No.: PCT/JP2013/061803

§ 371 Date: Oct. 20, 2014

(30) Foreign Application Priority Data
Apr. 23, 2012 (JP) 2012-097624

(51) Int. Cl. C23C 16/44; H01L 21/223; H01L 21/324; H01L 21/02

(52) U.S. Cl. CPC C23C 16/44; H01L 21/0262; H01L 21/02576; H01L 21/02579; H01L 21/2236; H01L 21/324
USPC 438/508; 118/704

(57) ABSTRACT

A film forming method according to an embodiment includes: (a) a step of supplying a first precursor gas of a semiconductor material into a processing vessel in which a processing target substrate is disposed, the first precursor gas being adsorbed onto the processing target substrate during the step; (b) a step of supplying a second precursor gas of a dopant material into the processing vessel, the second precursor gas being adsorbed onto the processing target substrate during the step; and (c) a step of generating the plasma of a reaction gas in the processing vessel, a plasma treatment being performed during the step so as to modify a layer adsorbed onto the processing target substrate.

### TECHNICAL FIELD

Exemplary embodiments of the present disclosure relate to a film forming method, and a film forming device, and a film forming system which may be used for performing the method, and more particularly, to film formation of a layer containing a dopant.

### BACKGROUND

In manufacturing a semiconductor device, for example, a large scale integrated circuit (LSI), a process is performed to form a planar type, fin type, or wire type MOSFET (metal oxide semiconductor field effect transistor) on some regions of a processing target substrate (silicon substrate). In such a process, a film forming processing and various plasma treatments or doping processings are performed using an ion implantation device, a plasma film forming device, or a thermal CVD device in order to form p-type or n-type conductive regions such as, for example, a source region, a drain region and/or an extension region, in addition to a process of forming a fine circuit pattern by photolithography.

In the process of forming the MOSFET, a technology such as, for example, solid phase diffusion, ion beam implantation, or plasma doping, is usually used in the doping processings. The solid phase diffusion refers to a technology of forming a deposition film layer containing an element to be doped (dopant) on a processing target substrate through a CVD method, or diffusing a dopant by heating the processing target substrate within a gas atmosphere containing the dopant. The ion beam implantation refers to a technology of implanting a dopant to a processing target substrate using an ion beam having a relatively high energy. In addition, as described in Patent Document 1, the plasma doping refers to a technology of directly implanting a dopant to a processing target substrate by generating plasma of a gas containing the dopant and applying an RF bias to the processing target substrate.

Meanwhile, according to recent miniaturization of LSI semiconductors, three-dimensionally structured LSI semiconductor devices attract attention. For example, in the case of MOSFET, a fin type or nanowire type MOSFET is being developed.

### PRIOR ART DOCUMENT

### Patent Document

Patent Document 1: Japanese Patent Laid-Open Publication No. 2008-300687

### SUMMARY OF THE INVENTION

### Problem to be Solved

In the above-described solid phase diffusion method, heating is generally performed at a very high temperature. Thus, a diffusion layer in a semiconductor device/LSI substrate becomes very deeper than a desired depth (diffusion depth). As a result, it is difficult to cope with miniaturization of semiconductor elements which is recently strongly demanded. In addition, in the solid phase diffusion, an ion diffusion direction may not be controlled which may cause a dopant to be diffused in a longitudinal direction of a channel. Consequently, a source region and a drain region may be connected with each other. In addition, in the ion beam implantation and the plasma doping, irradiation amounts of ions on a three-dimensionally structured semiconductor substrate surface, i.e. a plurality of differently oriented uneven surfaces are different from each other. Therefore, it is difficult to perform uniform doping on the plurality of surfaces.

Accordingly, what is requested in the related art is to form a film including a dopant uniformly to follow a three-dimensionally structured semiconductor substrate surface.

### Means to Solve the Problem

A film forming method according to an aspect of the present disclosure includes: (a) a step of supplying a first precursor gas of a semiconductor material into a processing vessel in which a processing target substrate is disposed, the first precursor gas being adsorbed onto the processing target substrate during the step; (b) a step of supplying a second precursor gas of a dopant material into the processing vessel, the second precursor gas being adsorbed onto the processing target substrate during the step; and (c) a step of generating plasma of a reaction gas within the processing vessel, a plasma treatment being performed during the step so as to modify a layer adsorbed onto the processing target substrate. In an exemplary embodiment, the plasma may be excited by microwaves.

The film forming method adsorbs the first precursor gas and the second precursor gas onto the processing target substrate by an atomic layer deposition (ALD) method and then, modifies an atom adsorption layer of a dopant adsorbed onto the processing target substrate by the plasma treatment. Thus, according to the present method, a film may be formed on a three-dimensionally structured surface, that is, a plurality of differently oriented surfaces uniformly and conformally. Meanwhile, the term, “conformally”, is used to express a situation in which doping is performed on a three-dimensionally structured surface uniformly without unevenness in concentration.

In an exemplary embodiment, the step of supplying the first precursor gas and the step of supplying second precursor gas may be separately performed. In this exemplary embodiment, the concentration of the dopant contained in the film formed on the processing target substrate may be adjusted based on a ratio of the number of times of performing the step of supplying the first precursor gas and the number of times of performing the step of supplying the second precursor gas. In an exemplary embodiment, the step of generating the plasma may include a step of performing a first plasma treatment and a step of performing a second plasma treatment. During the step of performing the first plasma treatment, the plasma treatment may be performed by the plasma of the reaction gas on a layer adsorbed onto the processing target substrate by the step of supplying the first precursor gas, and during the step of performing the second plasma treatment, the plasma treatment may be performed on a layer adsorbed onto the processing target substrate by the step of supplying the second precursor gas.

In an exemplary embodiment, each of the first precursor gas and the second precursor gas may further include hydrogen atoms and/or chlorine atoms, and during the step of performing the first plasma treatment and the step of performing the second plasma treatment, plasma of hydrogen gas which is a reaction gas may be excited. According to this exemplary embodiment, foreign matters other than the dopant may be removed from the layer adsorbed onto the processing target substrate by a reduction reaction using hydrogen.

In an exemplary embodiment, the step of supplying the first precursor gas and the step of supplying the second precursor gas may be performed simultaneously so that a mixture gas of the first precursor gas and the second precursor gas may be adsorbed onto the processing target substrate. In this exemplary embodiment, the concentration of the dopant contained in the film formed on the processing target substrate may be adjusted based on a ratio of the flow rate of the first precursor gas and the flow rate of the second precursor gas. In an exemplary embodiment, each of the first precursor gas and the second precursor gas may further include hydrogen atoms and/or chlorine atoms, and during the step of performing the first plasma treatment and the step of performing the second plasma treatment, plasma of hydrogen gas which is a reaction gas may be excited. According to this exemplary embodiment, foreign matters other than a desired dopant may be removed from the layer adsorbed onto the processing target substrate by a reduction reaction using hydrogen.

In addition, a film forming method according to an exemplary embodiment may further include a step of annealing the processing target substrate after a series of steps including the step in which the first precursor gas is adsorbed, the step in which the second precursor gas is adsorbed, and the step of generating the plasma are repeated one or more times. According to this exemplary embodiment, the film formed on the processing target substrate may be activated by annealing the processing target substrate.

In addition, a film forming method according to an exemplary embodiment may further include a step of forming a cap layer on a surface of the film formed on the processing target substrate prior to the step of annealing the processing target substrate. According to this exemplary embodiment, annealing may be performed while protecting the film formed through a series of the above-described steps, and as a result, the dopant contained in the film may be suppressed from being diffused outward from the film by the annealing. Therefore, reduction of the concentration of the dopant may be suppressed.

A film forming device according to another aspect of the present disclosure is provided with a processing vessel, a supply section, and a plasma generation section. A processing target substrate is disposed in the processing vessel. The supply section supplies a first precursor gas of a semiconductor material, and a second precursor gas of a dopant material into the processing vessel so that the first precursor gas and the second precursor gas are adsorbed onto the processing target substrate. The plasma generation section generates plasma of a reaction gas in the processing vessel so as to modify a layer adsorbed onto the processing target substrate by a plasma treatment. In an exemplary embodiment, the plasma generation section may use plasma excited by microwaves.

The film forming device may be intended to adsorb the first precursor gas and the second precursor gas onto the processing target substrate by an atomic layer deposition (ALD) method, and to modify a layer adsorbed onto the processing target substrate by the plasma treatment. According to the present film forming device, a film containing a dopant may be formed on a three-dimensionally structured semiconductor substrate surface uniformly and conformally.

A film forming device according to an exemplary embodiment may further include a control unit configured to control the supply section and the plasma generation section.

In an exemplary embodiment, the control unit may control: (a) the supply section to supply the first precursor gas into the processing vessel, (b) the plasma generation section to generate plasma of the reaction gas so as to perform a plasma treatment on a layer adsorbed onto the processing target substrate by supplying the first precursor gas, (c) the supply section to supply the second precursor gas into the processing vessel, and (d) the plasma generation section to generate plasma of the reaction gas so as to perform a plasma treatment on a layer adsorbed onto the processing target substrate by supplying the second gas. In this exemplary embodiment, the concentration of the dopant contained in the film formed on the processing target substrate may be adjusted based on a ratio of the number of times of supplying the first precursor gas and the number of times of supplying the second precursor gas.

In an exemplary embodiment, the supply section may supply a mixture gas of the first precursor gas and the second precursor gas into the processing vessel. The control unit may control the supply section to supply the mixture gas into the processing vessel, and control the plasma generation section to generate the plasma of the reaction gas so as to perform the plasma treatment on the layer adsorbed onto the processing target substrate by supplying the mixture gas. In this exemplary embodiment, the concentration of the dopant contained in the film formed on the processing target substrate may be adjusted based on a ratio of the flow rate of the first precursor gas and the flow rate of the second precursor gas.

In an exemplary embodiment, each of the first gas and the second gas may further include hydrogen atoms and/or chlorine atoms, and the plasma generation section may generate plasma of hydrogen gas which is the reaction gas. According to this exemplary embodiment, foreign matters other than the dopant may be removed from the layer adsorbed onto the processing target substrate by a reduction reaction using hydrogen.

A film forming system according to still another exemplary embodiment is a doping system using ALD film formation and is provided with a film forming device according to any one of the above-described aspects or exemplary embodiments and an annealing device configured to receive the processing target substrate processed by the film forming device, and anneal the processing target substrate. According to this film forming system, the film formed on the processing target substrate may be activated by annealing the processing target substrate.

A film forming system according to an exemplary embodiment may further include another ADD film forming device of a doping system. The another ALD film forming device may be connected with the film forming device through a vacuum conveyance system, and may receive the processing target substrate from the film forming device and form a cap layer on a surface of the processing target substrate. The annealing device may be connected to the separate film forming device and may anneal the processing target substrate conveyed from the separate film forming device. According to this exemplary embodiment, annealing may be performed while protecting the film formed on the processing target substrate, and as a result, the dopant contained in the film may be suppressed from escaping from the film.

### Effect of the Invention

As described above, according to various aspects and exemplary embodiments of the present disclosure, a film containing a dopant may be formed to follow a three-dimensionally structured surface with a high uniformity.

### BRIEF DESCRIPTION OF THE DRAWINGS

FIG. 1 is a plan view schematically illustrating a film forming system according to a first exemplary embodiment.

FIG. 2 is a cross-sectional view illustrating a film forming device according to an exemplary embodiment.

FIG. 3 is a top side view schematically illustrating the film forming device of the exemplary embodiment.

FIG. 4 is a plan view illustrating the film forming device illustrated in FIG. 3 in a state in which an upper part of a processing vessel is removed from the film forming device.

FIG. 5 is an enlarged cross-sectional view of a part of the film forming device illustrated in FIG. 2, in which a section taken by cutting a portion including the region R1 in parallel to the axis X is illustrated.

FIG. 6 is a plan view illustrating an injection portion of the gas supply section 16, an exhaust port of the exhaust section 18, and an injection port of the gas supply section 20 of the film forming device illustrated in FIG. 2 which are viewed from the lower side, i.e. from the mounting table side.

FIG. 7 is an exploded perspective view of a unit which defines the injection portion 16a, the exhaust port 18a, and the injection port 20a.

FIG. 8 is a plan view of the unit illustrated in FIG. 7 when viewed from the upper side.

FIG. 9 is an enlarged cross-sectional view of the film forming device illustrated in FIG. 2, in particular, a portion in which the plasma generation section is provided.

FIG. 10 is a plan view illustrating one antenna of a film forming device according to an exemplary embodiment, which is viewed from the upper side.

FIG. 11 is a cross-sectional view taken along line XI-XI in FIG. 10.

FIG. 12 is a perspective view illustrating an exemplary semiconductor device which may be manufactured using a film forming device of an exemplary embodiment.

FIG. 13 is a perspective view illustrating another exemplary semiconductor device which may be manufactured using a film forming device of an exemplary embodiment.

FIG. 14 is a flowchart illustrating a film forming method according to an exemplary embodiment.

FIG. 15 is a flowchart illustrating a film forming method according to another exemplary embodiment.

FIG. 16 is a cross-sectional view schematically illustrating a film forming device according to another exemplary embodiment.

### DETAILED DESCRIPTION TO EXECUTE THE INVENTION

Hereinafter, various exemplary embodiments will be described in detail with reference to drawings. In each drawing, the same or corresponding portions will be denoted by the same symbols.

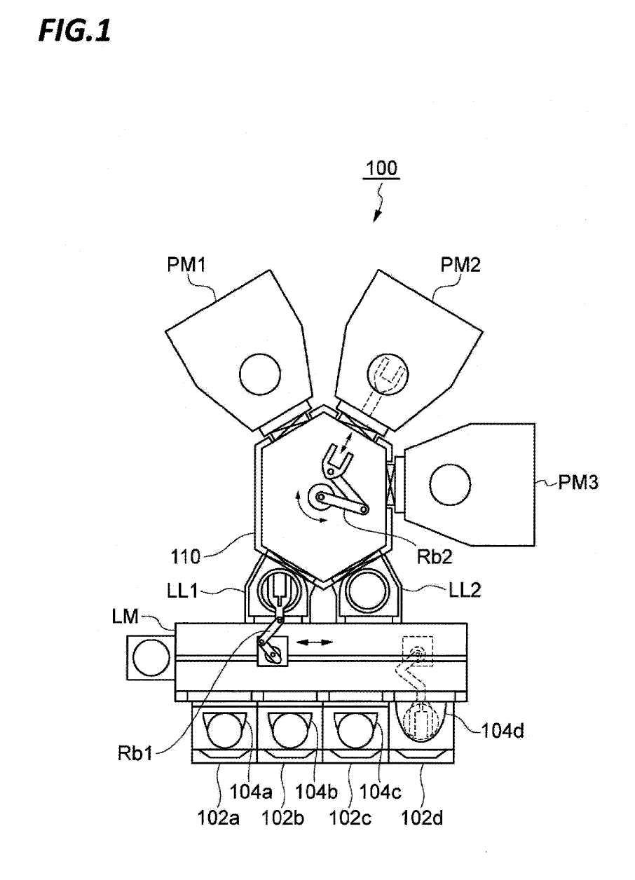

First, descriptions will be made on a film forming system of an exemplary embodiment provided with a film forming device of a doping system using ALD film formation according to an exemplary embodiment. FIG. 1 is a plan view schematically illustrating a film forming system according to an exemplary embodiment. The film forming system 100 is provided with mounting tables 102a to 102d, accommodation containers 104a to 104d, a loader module LM, load lock chambers LL1 and LL2, process modules PM1, PM2 and PM3, and a transfer chamber 110.

The mounting tables 102a to 102d are arranged along one edge of the loader module LM. Above the mounting tables 102a to 102d, the accommodation containers 104a to 104d are placed, respectively. A processing target substrate W is accommodated in each of the accommodation containers 104a to 104d.

A conveyance robot Rb1 is installed in the loader module LM. The conveyance robot Rb1 takes out a processing target substrate W accommodated in any one of the accommodation containers 104a to 104d, and conveys the processing target substrate W to a load lock chamber LL1 or LL2.

The load lock chambers LL1 and LL2 are installed along another edge of the loader module LM and form a preliminary decompression chamber. Each of the load lock chambers LL1 and LL2 is connected to the transfer chamber 110 through a gate valve.

The transfer chamber 110 is a chamber which may be decompressed, and another conveyance robot Rb2 is installed in the chamber. To the transfer chamber 110, the process modules PM1 to PM3 are connected through corresponding gate valves, respectively. The conveyance robot Rb2 takes out processing target substrates W from a load lock chamber LL1 or LL2, and sequentially conveys the processing target substrates W to the process module PM1, PM2, and PM3. Each of the process modules PM1, PM2 and PM3 of the film forming system 100 may be a film forming device of an exemplary embodiment, a separate film forming device, or an annealing device.

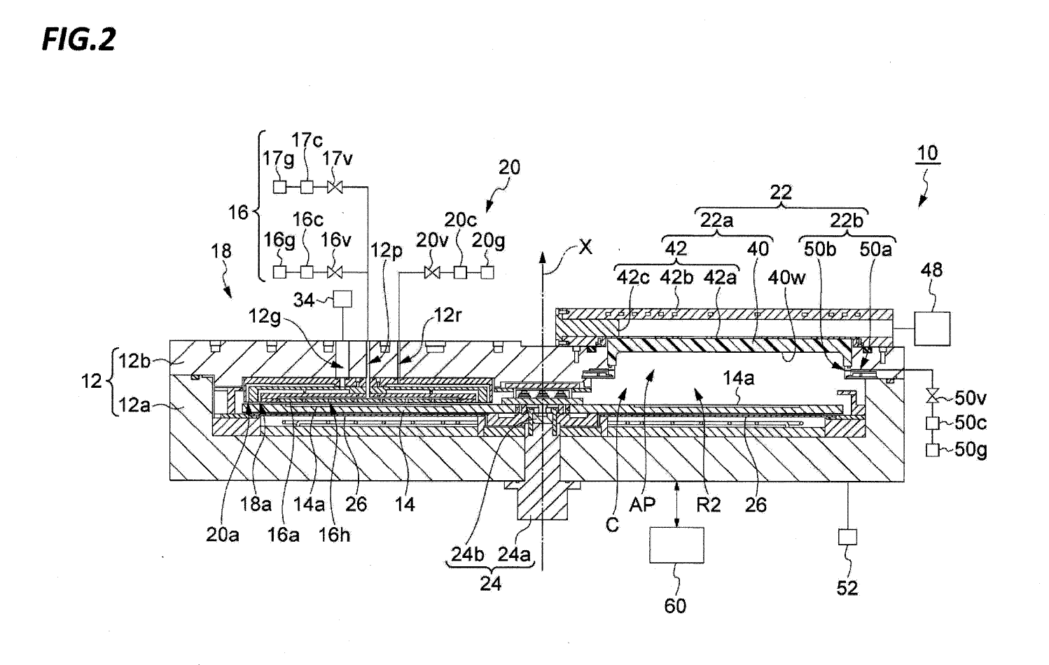

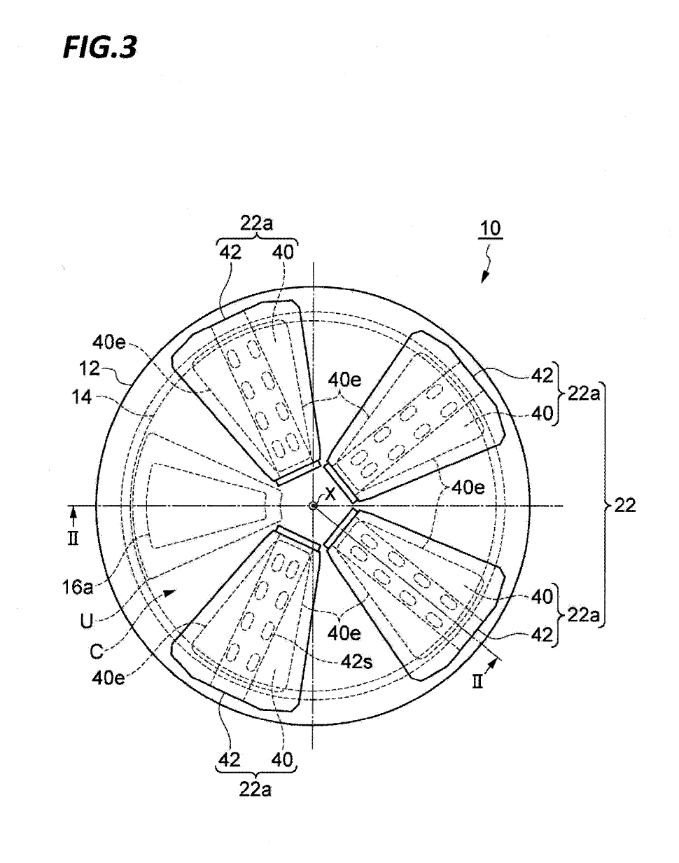

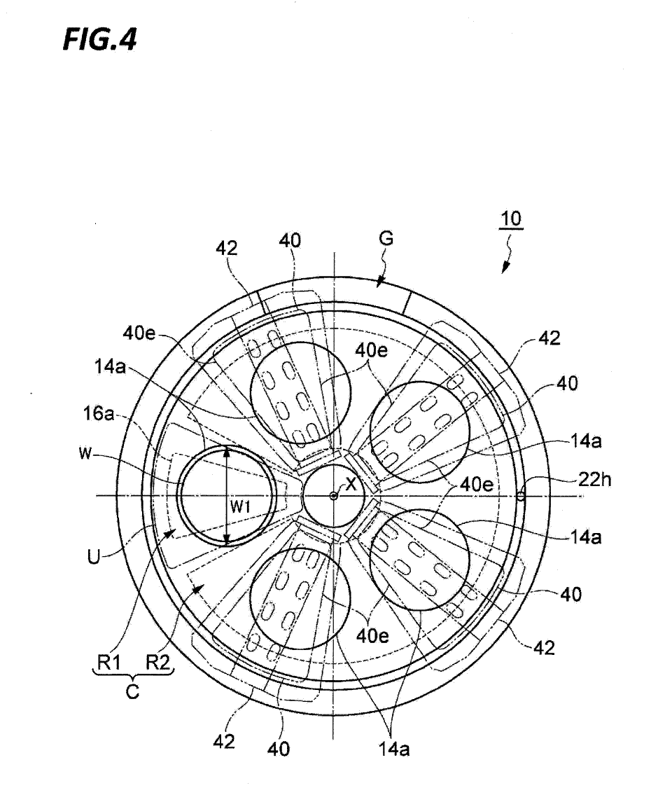

Hereinafter, descriptions will be made on a film forming device 10 of a doping system using ALD film formation according to an exemplary embodiment, in which the film forming device 10 may be used as a process module PM1. First, reference will be made to FIGS. 2 to 4. FIG. 2 is a cross-sectional view of a film forming device according to an exemplary embodiment. FIG. 3 is a top side view schematically illustrating the film forming device of the exemplary embodiment. FIG. 2 illustrates a section cut along line II-II in FIG. 3. FIG. 4 is a plan view illustrating the film forming device illustrated in FIG. 3 in a state in which an upper part of a processing vessel is removed from the film forming device. The film forming device 10 illustrated in FIGS. 2 to 4 is a so-called semi-batch type film forming device which performs film formation by the ALD method. The film forming device 10 is provided with a processing vessel 12, a mounting table 14, a gas supply section 16, an exhaust section 18, a gas supply section 20, and a plasma generation section 22.

The processing vessel 12 is a substantially cylindrical container extending in an axis X direction. The processing vessel 12 defines a processing chamber C therein. The inner surface of the processing vessel 12 may be made of a metal, for example, aluminum subjected to a plasma resistance treatment (e.g., alumite treatment or thermal spray treatment of Y₂O₃). In an exemplary embodiment, as illustrated in FIG. 2, the processing vessel 12 includes a lower part 12a and an upper part 12b. The lower part 12a has a top opened cylinder shape, and includes a side wall and a bottom wall which define the processing chamber C. The upper part 12b is a closure that defines the processing chamber C from the upper side. The upper part 12b is attached to the top portion of the lower part 12a to close the top opening of the lower part 12a. An elastic sealing member may be installed between the lower part 12a and the upper part 12b to seal the processing chamber C.

The mounting table 14 is installed within the processing chamber C defined by the processing vessel 12. The mounting table 14 has substantially a disc shape. The mounting table 14 is configured to be rotatable about the axis X. In an exemplary embodiment, the mounting table 14 is rotationally driven about the axis X by a driving mechanism 24. The driving mechanism 24 includes a driving device 24a such as a motor and a rotation shaft 24b, and is attached to the lower part 12a of the processing vessel 12. The rotation shaft 24b extends to the inside of the processing chamber C to be centered on the axis X as a central axis thereof, and is rotated about the axis X by a driving force from the driving device 24a. A central portion of the mounting table 14 is supported on the rotation shaft 24b. As a result, the mounting table 14 is rotated about the axis X. In addition, an elastic sealing member such as, for example, an O-ring may be installed between the lower part 12a of the processing vessel 12 and the driving mechanism 24.

As illustrated in FIGS. 2 and 4, one or more mounting regions 14a may be provided on the top surface of the mounting table 14. In an exemplary embodiment, a plurality of mounting regions 14a is arranged around the axis X. Each mounting region 14a is formed as a recess having a diameter which is approximately equal to or slightly larger than the diameter of a processing target substrate W mounted thereon. In the processing chamber C, a heater 26 is installed below the mounting table 14 so as to heat the processing target substrate W mounted on a mounting region 14a. The processing target substrate W is conveyed to the processing chamber C through a gate valve G provided in the processing vessel 12, and mounted on the mounting region 14a by a conveyance robot. In addition, after having been subjected to a processing by the film forming device 10, the processing target substrate W is taken out from the processing chamber C through the gate valve G by the conveyance robot. The processing chamber C includes a first region R1 and a second region R2 arranged around the axis X. Accordingly, a processing target substrate W mounted on a mounting region 14a sequentially passes through the first region R1 and the second region R2, following the rotation of the mounting table 14.

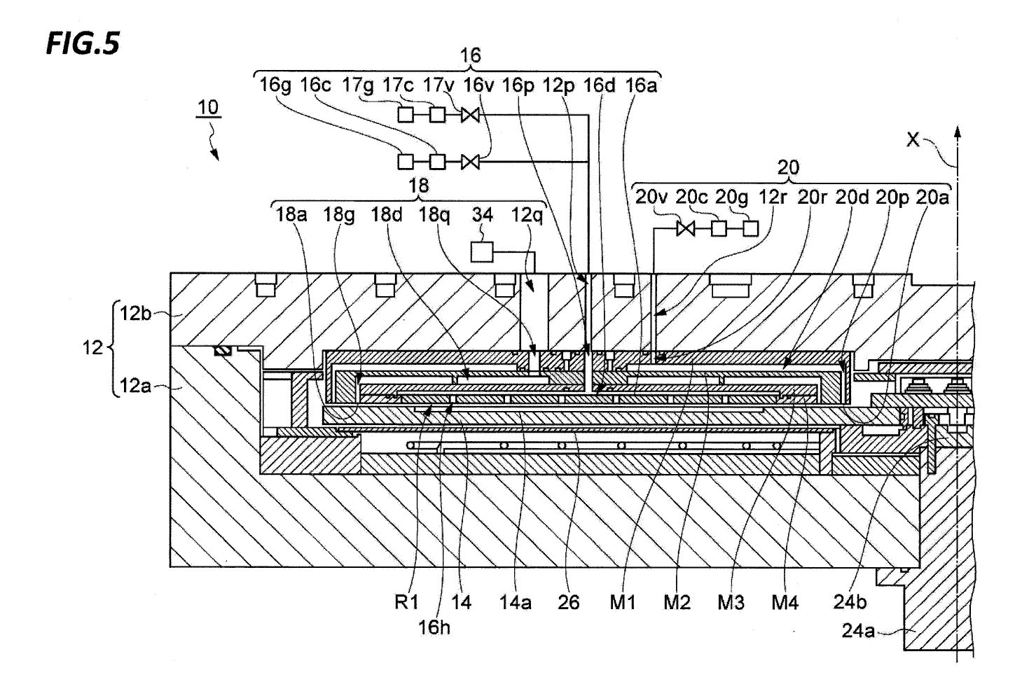

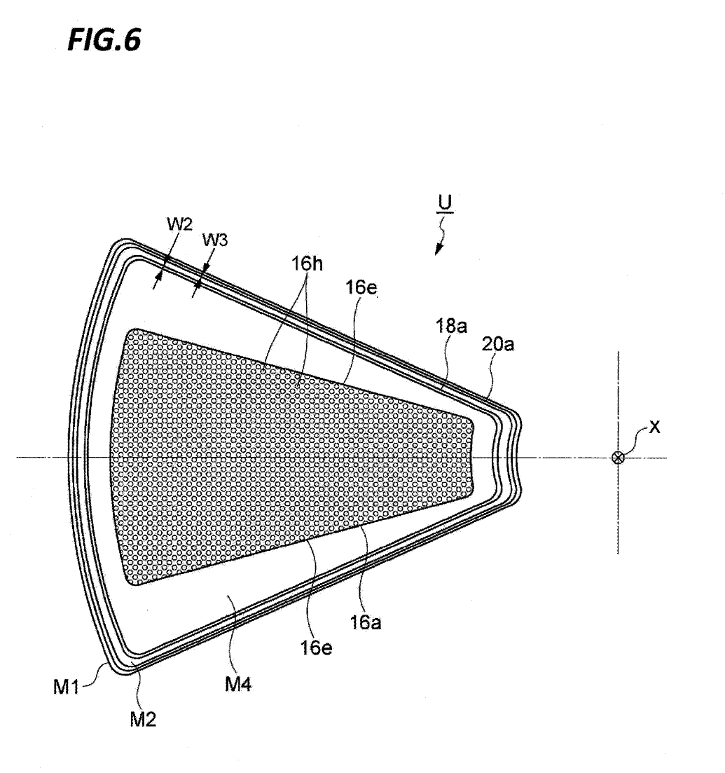

Hereinafter, reference will be made to FIGS. 5 and 6 in addition to FIGS. 3 and 4. FIG. 5 is an enlarged cross-sectional view of a part of the film forming device illustrated in FIG. 2 in which a section taken by cutting a portion including the region R1 in parallel to the axis X is illustrated. FIG. 6 is a plan view illustrating an injection portion of the gas supply section 16, an exhaust port of the exhaust section 18, and an injection port of the gas supply section 20 of the film forming device illustrated in FIG. 2 which are viewed from the lower side, i.e. from the mounting table side. As illustrated in FIGS. 3 to 6, an injection portion 16a of the gas supply section 16 is provided above a first region R1 to face the top surface of the mounting table 14. In other words, in the region included in the processing chamber C, a region facing the injection portion 16a becomes the first region R1.

As illustrated in FIGS. 5 and 6, the injection portion 16a is formed with a plurality of injection ports 16h. The gas supply section 16 supplies a precursor gas to the first region R1 from the plurality of injection ports 16h. When the precursor gas is supplied to the first region R1, the precursor gas is chemically adsorbed onto a surface of a processing target substrate W which passes through the first region R1.

In an exemplary embodiment, the precursor gas supplied from the injection portion 16a to the first region R1 includes a first precursor gas and a second precursor gas. The first precursor gas is a precursor gas of a semiconductor material. In an exemplary embodiment, the first precursor gas may include silicon as the semiconductor material, and may further include chlorine atoms and/or hydrogen atoms. The first precursor gas is, for example, dichlorosilane (DCS). The second precursor gas is a precursor gas of a dopant material. The second precursor gas may include arsenic or phosphor as an n-type dopant material. In addition, the second precursor gas may include chlorine atoms and/or hydrogen atoms. The second precursor gas is, for example, AsClH₂ gas. Or, the second precursor gas may include boron as a p-type dopant material, and may further include chlorine atoms and/or hydrogen atoms. The second precursor gas is, for example, B(CH₃)₂H gas. In addition, the first precursor gas and the second precursor gas may be supplied from the injection portion 16a in a switching manner, or a mixture gas of the first and second precursor gases may be supplied.

In an exemplary embodiment, as illustrated in FIG. 6, the edges defining the injection portion 16a includes two edges 16e defining the injection portion 16a from the circumferential direction. The two edges 16e extend to approach each other as approaching the axis X. The two edges 16e may extend, for example, in a radial direction with respect to the axis X. That is, the injection portion 16a may have substantially a fan shape in a plan view. The plurality of injection ports 16h is provided between the two edges 16e. Here, a speed of each position within the processing target substrate W following the rotation of the mounting table 14 is varied depending on a distance from the axis X. That is, the speed at a position is increased in proportion to the distance from the axis X to the position. In the present exemplary embodiment, the injection portion 16a is configured such that the processing target substrate W faces more injection ports 16h at a position spaced farther away from the axis X. Accordingly, variations in exposure time for respective positions on the processing target substrate W with respect to the precursor gases may be reduced.

As illustrated in FIGS. 5 and 6, an exhaust port 18a is provided around the injection portion 16a, and the exhaust section 18 evacuates the first region R1 from the exhaust port 18a. The exhaust port 18a of the exhaust section 18 faces the top surface of the mounting table 14 and, as illustrated in FIG. 6, extends along a closed path surrounding the outer circumference of the injection portion 16a. Thus, in the film forming device 10, a narrow exhaust port 18a surrounds the injection portion 16a.

In addition, as illustrated in FIGS. 5 and 6, an injection port 20a of the gas supply section 20 is provided around the exhaust port 18a, and the gas supply section 20 injects a purge gas from the injection port 20a. The injection port 20a of the gas supply section 20 faces the top surface of the mounting table 14, and extends along a closed path that surrounds the outer circumference of the exhaust port 18a. As for the purge gas supplied by the gas supply section 20, for example, an inert gas such as, for example, Ar gas or N₂ gas, may be used. When the purge gas is sprayed on the processing target substrate W, the precursor gas chemically adsorbed excessively on the processing target substrate W is removed in such a manner that an amount excessively adsorbed in addition to an adsorption amount of the first element is removed.

In the film forming device 10, by exhaust from the exhaust port 18a and injection of the purge gas from the injection port 20a, the precursor gas supplied to the first region R1 is suppressed from leaking to the outside of first region R1, and, for example, a reaction gas supplied in the second region R2 as described below or radicals thereof are also suppressed from infiltrating into the first region R1. That is, the exhaust section 18 and the gas supply section 20 separate the first region R1 and the second region R2 from each other. In addition, the injection port 20a and the exhaust port 18a has a stripe shape in a plan view which extends along the closed path surrounding the outer circumference of the injection portion 16a. Thus, the width of each of the injection port 20a and the exhaust port 18a is narrowed. Accordingly, the separation between the first region R1 and the second region R2 may be realized while securing an angular range of the second region R2 extending in the circumferential direction with respect to the axis X. In an exemplary embodiment, the width W2 of the exhaust port 18a and the width W3 of the injection port 20a extending between the first region R1 and second region R2 (see FIG. 6) is smaller than the diameter W1 of the mounting regions 14a (see FIG. 4).

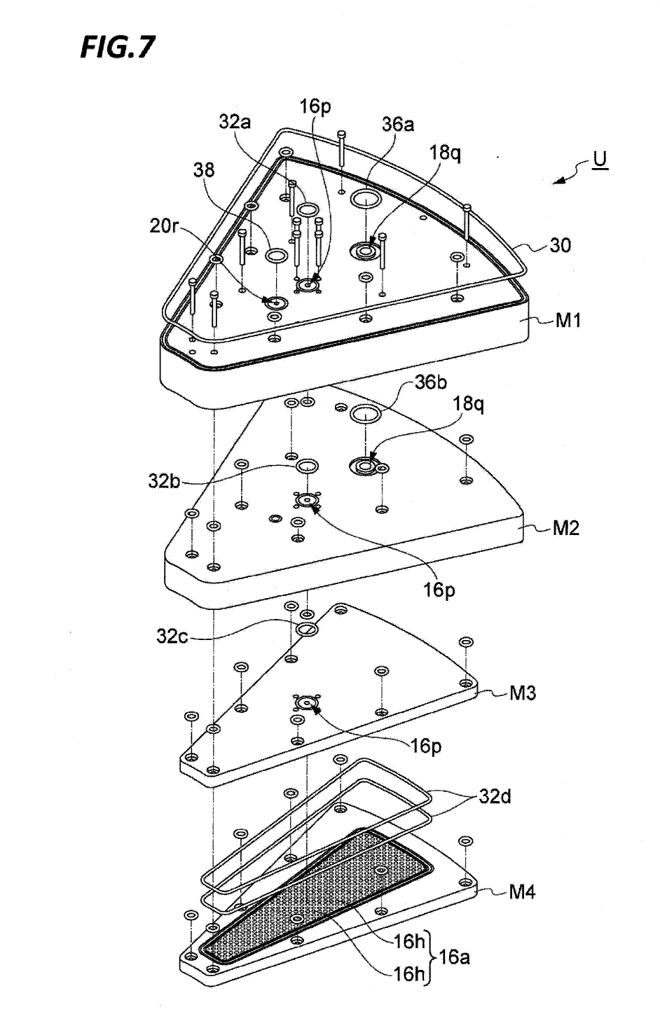

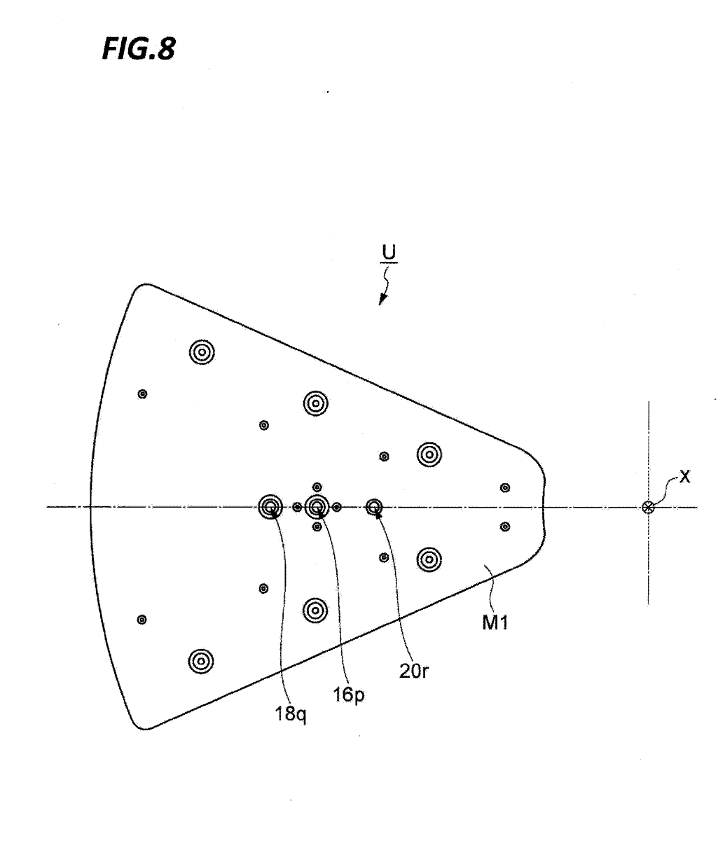

In an exemplary embodiment, the film forming device 10 may be provided with a unit U which defines the injection portion 16a, the exhaust port 18a, and the injection port 20a. Hereinafter, reference will be made to FIGS. 7 and 8. FIG. 7 is an exploded perspective view of the unit which defines the injection portion 16a, the exhaust port 18a, and the injection port 20a. FIG. 8 is a plan view of the unit illustrated in FIG. 7 when viewed from the upper side. The top surface of the unit U is illustrated in FIG. 8, and the bottom surface of the unit U is illustrated in FIG. 6. As illustrated in FIGS. 5 to 8, the unit U includes a first member M1, a second member M2, a third member M3, and a fourth member M4 in which the first to fourth members M1 to M4 are stacked in this order from the top. The unit U is attached to the processing vessel 12 to be abutted on the bottom surface of the upper part 12b of the processing vessel 12, and the elastic sealing member 30 is provided between the bottom surface of the upper part 12b of the processing vessel 12 and the first member M1. The elastic sealing member 30 extends along the outer edge of the top surface of the first member M1.

Each of the first to fourth members M1 to M4 has substantially a fan shape in a plan view. The first member M1 defines a recess at the bottom side thereof, in which the second to fourth members M2 to M4 are received. In addition, the second member M2 defines a recess at the bottom side thereof, in which the third and fourth members M3 and M4 are received. The third member M3 and the fourth member M4 have plane sizes which are substantially equal to each other.

In the unit U, a gas supply path 16p is formed through the first to third members M1 to M3. The gas supply path 16p is connected, at the upper end thereof, with a gas supply path 12p provided in the upper part 12b of the processing vessel 12. A gas source 16g of the first precursor gas is connected to the gas supply path 12p through a valve 16v and a flow rate controller 17c such as a mass flow controller. In addition, the lower end of the gas supply path 16p is connected to a space 16d formed between the third member M3 and the fourth member M4. The injection ports 16h of the injection portion 16a installed in the fourth member M4 are connected to the space 16d.

Between the upper part 12b of the processing vessel 12 and the first member M1, an elastic sealing member 32a such as, for example, an O-ring is provided to surround a connection portion between the gas supply path 12p and the gas supply path 16p. By the elastic sealing member 32a, the precursor gas supplied to the gas supply path 16p and the gas supply path 12p may be prevented from leaking out from the boundary between the upper part 12b of the processing vessel 12 and the first member M1. In addition, elastic sealing members 32b and 32c such as, for example, O-rings may be installed between the first member M1 and the second member M2, and between the second member M2 and the third member M3, respectively, to surround the gas supply path 16p. By the elastic sealing members 32b and 32c, the precursor gas supplied to the gas supply path 16p may be prevented from leaking out from the boundary between the first member M1 and the second member M2 and the boundary between the second member M2 and the third member M3. Further, an elastic sealing member 32d is installed between the third member M3 and the fourth member M4 to surround the space 16d. By the elastic sealing member 32d, the precursor gas supplied to the space 16d may be prevented from leaking out from the boundary between the third member M3 and the fourth member M4.

In addition, in the unit U, an exhaust path 18q is formed through the first and second members M1 and M2. The exhaust path 18q is connected, at the upper end thereof, with an exhaust path 12q provided in the upper part 12b of the processing vessel 12. The exhaust path 12q is connected to an exhaust device 34 such as, for example, a vacuum pump. In addition, the exhaust path 18q is connected, at the lower end thereof, to a space 18d provided between the bottom surface of the second member M2 and the top surface of the third member M3. In addition, as described above, the second member M2 defines a recess that accommodates the third member M3 and the fourth member M4, and a gap 18g is provided between the inner surface of the second member M2 that defines the recess and the lateral end surfaces of the third member M3 and the fourth member M4. The space 18d is connected to the gap 18g. The lower end of the gap 18g functions as the above-described exhaust port 18a.

Between the upper part 12b of the processing vessel 12 and the first member M1, an elastic sealing member 36a such as, for example, an O-ring is installed to surround the connection portion between the exhaust path 18q and the exhaust path 12q. By the elastic sealing member 36a, the exhaust gas passing through the exhaust path 18q and the exhaust path 12q may be prevented from leaking out from the boundary between the upper part 12b of the processing vessel 12 and the first member M1. In addition, between the first member M1 and the second member M2, an elastic sealing member 36b such as, for example, an O-ring is installed to surround the exhaust path 18q. By the elastic sealing member 36b, the gas passing through the exhaust path 18q may be prevented from leaking out from the boundary between the first member M1 and the second member M2.

In the unit U, a gas supply path 20r is formed through the first member M1. The gas supply path 20r is connected, at the upper end thereof, with a gas supply path 12r provided in the upper part 12b of the processing vessel 12. To the gas supply path 12r, a gas source 20g of a purge gas is connected through a valve 20v and a flow rate controller 20c such as a mass flow controller. In addition, the lower end of the gas supply path 20r is connected to a space 20d provided between the bottom surface of the first member M1 and the top surface of the second member M2. In addition, as described above, the first member M1 defines the recess that accommodates the second to fourth members M2 to M4, and a gap 20p is formed between the inner surface of the first member M1 which defines the recess and the lateral surface of the second member M2. The gap 20p is connected to the space 20d. In addition, the lower end of the gap 20p functions as the injection port 20a of the gas supply section 20. Between the upper part 12b of the processing vessel 12 and the first member M1, an elastic sealing member 38 such as, for example, an O-ring is installed to surround a connection portion between the gas supply path 12r and the gas supply path 20r. By the elastic sealing member 38, the purge gas passing through the gas supply path 20r and the gas supply path 12r may be prevented from leaking out from the boundary between the upper part 12b and the first member M1.

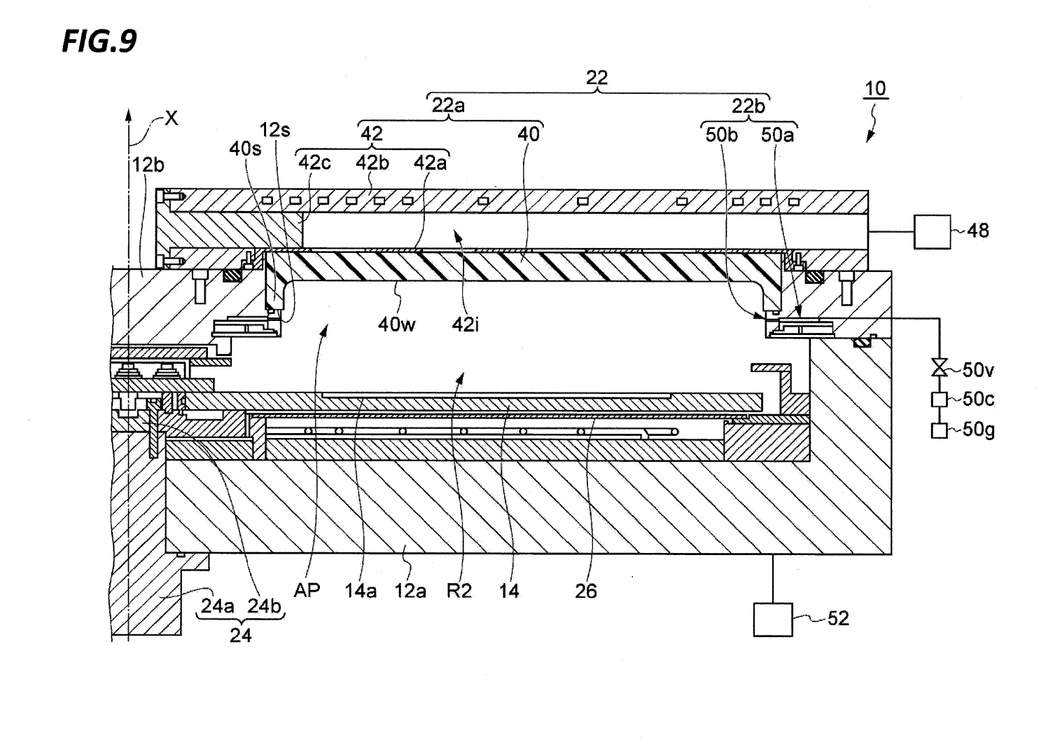

Hereinafter, FIGS. 2 to 4 will be referred to again, together with FIG. 9. FIG. 9 is an enlarged cross-sectional view of the film forming device illustrated in FIG. 2, in particular, a portion in which the plasma generation section is provided. As illustrated in FIGS. 2 to 4 and FIG. 9, the film forming device 10 is provided with a plasma generation section 22. The plasma generation section 22 supplies a reaction gas to the second region R2, and supplies microwaves to the second region R2. Thus, plasma of the reaction gas is generated in the second region R2 to perform a plasma treatment on a plasma gas layer adsorbed onto a processing target substrate W. In the second region R2, the precursor gas chemically adsorbed onto the processing target substrate W, i.e. the precursor gas layer may be modified by the plasma of the reaction gas. As for the reaction gas, for example, H₂ gas may be used.

The plasma generation section 22 may include one or more antennas 22a configured to supply microwaves to the second region R2. Each of the one or more antennas 22a may include a dielectric plate 40 and one or more waveguides 42. In the exemplary embodiment illustrated in FIGS. 2 to 4, four antennas 22a are arranged around the axis X. Each antenna 22a includes a dielectric plate 40 provided above the second region R2, and a waveguide 42 provided on the dielectric plate 40.

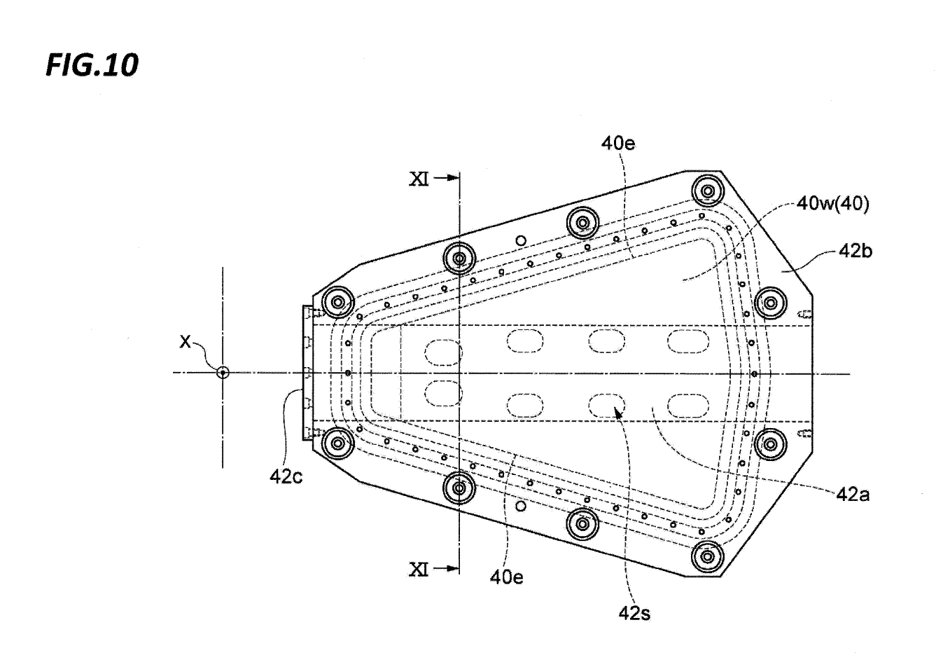

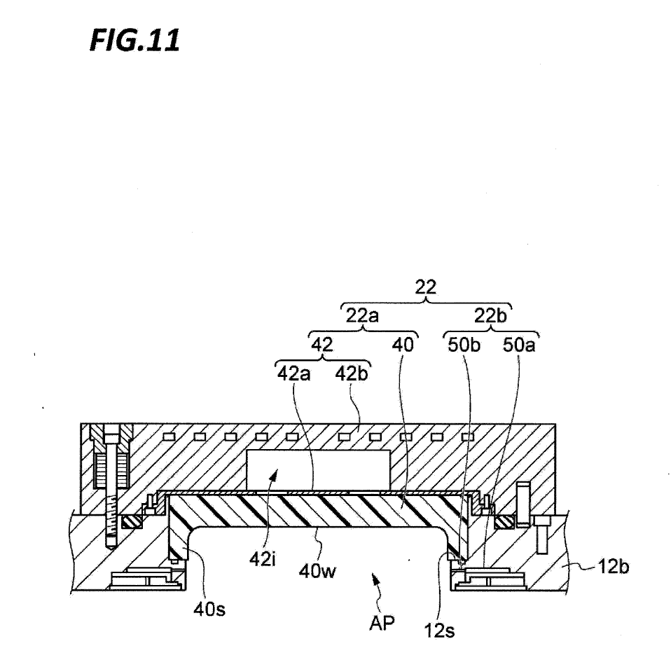

Here, reference is also made to FIGS. 10 and 11. FIG. 10 is a plan view illustrating one antenna of a film forming device according to an exemplary embodiment, when viewed from the upper side. FIG. 11 is a cross-sectional view taken along line XI-XI in FIG. 10. As illustrated in FIGS. 9 to 11, the dielectric plate 40 is a substantially plate-shaped member which is made of a dielectric material such as quartz. The dielectric plate 40 is installed to face the second region R2 and supported by the upper part 12b of the processing vessel 12.

Specifically, in the upper part 12b of the processing vessel 12, an aperture AP is formed such that the dielectric plate 40 is exposed to the second region R2. A plane size of the upper portion of the aperture AP (a size in a plane intersecting the axis X) is larger than a plane size of the lower portion of the aperture AP (a size in the plane intersecting the axis X). Accordingly, a stepped surface 12s facing upward is formed in the upper part 12b defining the aperture AP. Meanwhile, the edge of the dielectric plate 40 functions as a supported portion 40s and abutted on the stepped surface 12s. When the supported portion 40s is abutted on the stepped surface 12s, the dielectric plate 40 is supported on the upper part 12b. In addition, an elastic sealing member may be installed between the stepped surface 12s and the dielectric plate 40.

The dielectric plate 40 supported by the upper part 12b as described above faces the mounting table 14 through the second region R2. In the bottom surface of the dielectric plate 40, a portion exposed from the aperture AP of the upper part 12b, that is, the portion facing the second region R2, functions as a dielectric window 40w. The edges of the dielectric window 40w include two edges 40e which approach each other as approaching the axis X. Due to the shape of the dielectric window 40w, that is, the shape in which the circumferential length increases in proportion to the distance from the axis X, variations in exposure time for respective positions on the processing target substrate W in relation to the plasma of the reaction gas may be reduced. In addition, in a plan view, the dielectric plate 40 including the dielectric window 40w and the supported portion 40s may be formed substantially in a fan shape, or in a polygonal shape so as to facilitate the machining thereof.

A waveguide 42 is installed on the dielectric plate 40. The waveguide 42 is a rectangular waveguide, and an internal space 42i in which the microwaves propagate is provided on the dielectric plate 40 to extend substantially in a radial direction with respect to the axis X in the upper side of dielectric window 40w. In an exemplary embodiment, the waveguide 42 may include a slot plate 42a, an upper member 42b, and an end member 42c.

The slot plate 42a is a plate-shaped member made of a metal, and defines the internal space 42i of the waveguide 42 from the bottom side thereof. The slot plate 42a is in contact with the top surface of the dielectric plate 40 to cover the top surface of the dielectric plate 40. The slot plate 42a includes a plurality of slot holes 42s in the portion defining the internal space 42i.

On the slot plate 42a, the upper member 42b made of a metal is installed to cover the slot plate 42a. The upper member 42b defines the internal space 42i of the waveguide 42 from the top side thereof. The upper member 42b may be fastened to the upper part 12b of the processing vessel 12 to sandwich the slot plate 42a and the dielectric plate 40 between the upper member 42b and the upper part 12b of the processing vessel 12.

The end member 42c is made of a metal, and installed on a longitudinal end portion of the waveguide 42. That is, the end member 42c is attached to one ends of the slot plate 42a and the upper member 42b to close one end of the internal space 42i. A microwave generator 48 is connected to the other end of the waveguide 42. The microwave generator 48 may generate microwaves of, for example, about 2.45 GHz, and supply the microwaves to the waveguide 42. The microwaves generated by the microwave generator 48 and propagated to the waveguide 42 are supplied to the dielectric plate 40 through the slot holes 42s of the slot plate 42a, and supplied to the second region R2 through the dielectric window 40w. In an exemplary embodiment, the microwave generator 48 may be commonly shared by a plurality of waveguides 42. In another exemplary embodiment, a plurality of microwave generators 48 may be connected to a plurality of waveguides 42, respectively. When the intensity of the microwaves generated by the microwave generators 48 is adjusted using one or more microwave generator 48 connected to a plurality of antennas 22a as described above, the intensity of the microwaves imparted to the second region R2 may be enhanced.

In addition, the plasma generation section 22 includes a gas supply section 22b. The gas supply section 22b supplies a reaction gas to the second region R2. As described above, the reaction gas serves to modify a precursor gas layer chemically adsorbed onto a processing target substrate W, and may be, for example, H₂ gas. In an exemplary embodiment, the gas supply section 22b may include a gas supply path 50a and an injection port 50b. The gas supply path 50a is formed in the upper part 12b of the processing vessel 12 to extend, for example, around the aperture AP. In addition, in the upper part 12b of the processing vessel 12, the injection port 50b is formed to inject the reaction gas supplied to the gas supply path 50a toward the lower side of the dielectric window 40w. In an exemplary embodiment, a plurality of injection ports 50b may be provided around the aperture AP. In addition, a gas source 50g of the reaction gas may is connected to the gas supply path 50a through a valve 50v and a flow rate controller 50c such as a mass flow controller.

According to the plasma generation section 22 configured as described above, the reaction gas is supplied to the second region R2 by the gas supply section 22b, and in addition, microwaves are supplied to the second region R2 by the antenna 22a. As a result, plasma of the reaction gas is generated in the second region R2. In other words, the second region R2 is a region where the plasma of the reaction gas is generated. As illustrated in FIG. 4, the angular range of the second region R2 extending in the circumferential direction with respect to the axis X is wider than the angular range of the first region R1 extending in the circumferential direction. The precursor gas layer chemically adsorbed onto the processing target substrate W is modified by the plasma of the reaction gas generated in the second region R2. In addition, as illustrated in FIG. 4, in the lower part 12a of the processing vessel 12, an exhaust port 22h is formed below the outer edge of the mounting table 14. To the exhaust port 22h, an exhaust device 52 illustrated in FIG. 9 is connected.

Referring to FIG. 2 again, the film forming device 10 may further include a control unit 60 configured to control respective elements of the film forming device 10. The control unit 60 may be a computer which is provided with, for example, a central processing unit (CPU), a memory, and an input device. When the CPU is operated according to a program stored in the memory in the control unit 60, each element of the film forming device 10 may be controlled. In an exemplary embodiment, the control unit 60 may transmit: a control signal to the driving device 24a so as to control the rotating speed of the mounting table 14; a control signal to the power source connected to the heater 26 so as to control the temperature of the processing target substrate W; a control signal to the valve 16v and the flow rate controller 16c so as to control the flow rate of the first precursor gas; a control signal to the valve 17v and the flow rate controller 17c so as to control the flow rate of the second precursor gas; a control signal to the exhaust device 34 connected to the exhaust port 18a so as to control the exhaust amount of the exhaust device 34; a control signal to the valve 20b and the flow rate controller 20c so as to control the flow rate of the purge gas; a control signal to the microwave generator 48 so as to control the microwave power; a control signal to the valve 50v and the flow rate controller 50c so as to control the flow rate of the reaction gas; and a control signal to the exhaust device 52 so as to control the exhaust amount of the exhaust device 52.

The film forming device 10 may cause the first precursor gas to be chemically adsorbed onto the surface of the processing target substrate W in the first region R1, and modify the first precursor gas layer adsorbed onto the processing target substrate W by the plasma of the reaction gas in the second region R2. For example, in a case where the first precursor gas is DCS, the film forming device 10 may extract chlorine from the DCS layer chemically adsorbed onto the surface of the processing target substrate W by a reduction reaction by the plasma of hydrogen gas, and form a silicon atom film on the surface of the processing target substrate W. In addition, the film forming device 10 may cause the second precursor gas to be chemically adsorbed onto the surface of the processing target substrate W in the first region R1, and modify the second precursor gas layer adhered to the processing target substrate W by the plasma of the reaction gas in the second region R2. For example, in a case where the second precursor gas is AsClH₂ gas, the film forming device 10 may extract chlorine from the AsClH₂ gas layer chemically adsorbed onto the surface of the processing target substrate W by the reduction reaction by the plasma of the hydrogen gas, and form an As atom layer on the surface of the processing target substrate W. In addition, the pressure of the second region R2 is preferably 1 Torr (133.3 Pa) or higher. For example, the pressure of the second region R2 is preferably in a range of 1 Torr (133.3 Pa) to 50 Torr (6666 Pa), and more preferably, in a range of 1 Torr (133.3 Pa) to 10 Torr (1333 Pa. When the plasma of the hydrogen gas is excited under the pressure, a lot of hydrogen ions are produced, and the reduction action for extracting chlorine from the first precursor gas layer and the second precursor gas layer may be exhibited more suitably.

In addition, in the film forming device 10, the gas to be supplied to the first region R1 while the processing target substrate W passes through the first region R1 by the rotation of the mounting table 14 may be selected from the first precursor gas and the second precursor gas. Accordingly, in the film forming device 10, the concentration of a dopant in a film formed on the processing target substrate W may be adjusted by adjusting a ratio of the number of times of supplying the first precursor gas to the first region R1 and the number of times of supplying the second precursor gas to the first region R1.

In addition, in another exemplary embodiment, the film forming device 10 may supply a mixture gas of the first precursor gas and the second precursor gas to the first region R1. In this exemplary embodiment, the concentration of the dopant in the film formed on the processing target substrate W may be adjusted by adjusting a ratio of the flow rate of the first precursor gas and the flow rate of the second precursor gas in the mixture gas.

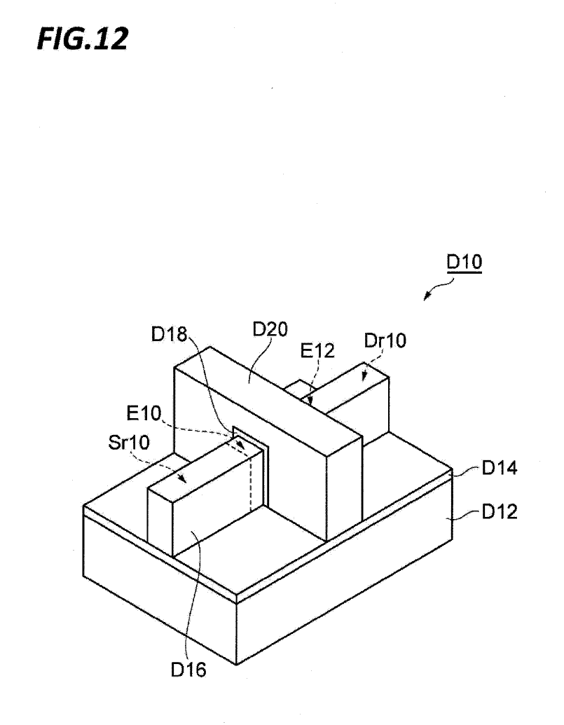

Next, an example of a semiconductor/an LSI, for which film formation by the film forming device 10 may be properly used, will be described. FIG. 12 is a perspective view illustrating an exemplary semiconductor device which may be manufactured using the film forming device of an exemplary embodiment. The semiconductor device D10 illustrated in FIG. 12 is a fin type MOS transistor. The semiconductor device D10 includes a substrate D12, an insulation film D14, a fin D16, a gate insulation film D18, and a gate electrode D20. The insulation film D14 is provided on the substrate D12. The fin D16 has a substantially rectangular parallelepiped shape, and provided on the insulation film D14. The gate insulation film D18 is provided to cover a side surface and a top surface of a portion of the fin D16. The gate electrode D20 is provided on the gate insulation film D18.

In the semiconductor device D10, extension regions E10 and E12 containing a low-concentration dopant are formed on the fin D16 at both sides of the insulation film D18. In addition, in the semiconductor device D10, a source region Sr10 and a drain region Dr10 containing a high-concentration dopant are additionally formed on the fin D16 adjacent to the extension regions E10 and E12.

The fin D16 of the semiconductor device D10 has a three-dimensional shape, i.e. a top surface and side surfaces, as illustrated in FIG. 12. Because the film forming device 10 may perform film formation based on the ALD method, the film formation may also be performed on the three-dimensional shape, that is, the top surface and side surfaces. Accordingly, according to the film forming device 10, it is possible to form the extension regions, the source region, and the drain region on the side surfaces and top surface of the fin D16 with a uniform film thickness.

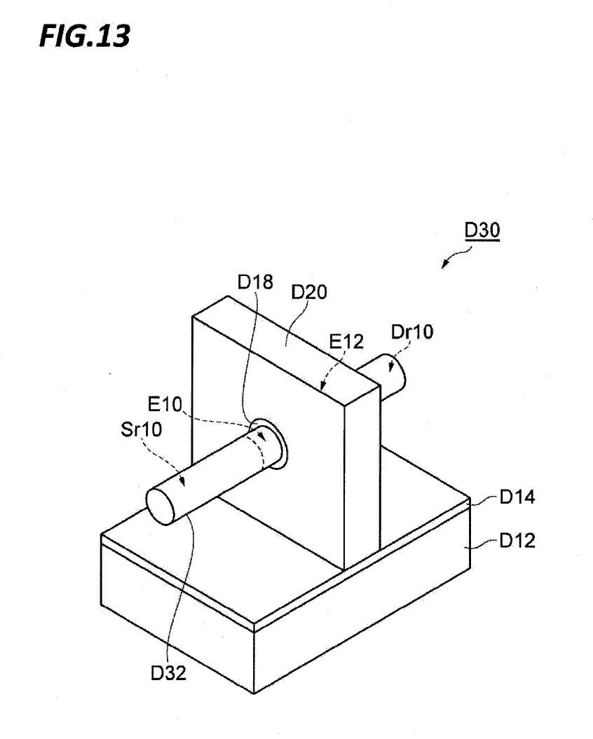

In addition to the fin type MOS transistor, the film forming device 10 may also be properly used for manufacturing a semiconductor device D30 illustrated in FIG. 13. The semiconductor device D30 illustrated in FIG. 13 is a nanowire type MOS transistor which includes a nanowire portion D32 having a substantially columnar shape, instead of the fin D16 of the above-described semiconductor device D10. In the semiconductor device D30, a gate insulation film D18 is formed on the entire surface of a part of the nanowire portion D32 in the longitudinal direction, and a gate electrode D20 is formed to cover the gate insulation film D18. In the semiconductor device D30, extension regions E10 and E12 are also formed on the nanowire portion D32 at both sides of the insulation film, and a source region and a drain region are formed next to the extension regions. According to the film forming device 10, it is possible to form the extension regions, the source region Sr10, and the drain region Dr10 over three-dimensional surfaces of the nanowire portion D32 with a uniform film thickness. In addition, the film forming device 10 may also be used for forming an extension region, a source region, and a drain region of a planar-type MOS transistor.

Hereinafter, reference will be made to FIG. 1 again. After the film formation is performed by the film forming device 10, the process module PM2 receives a processing target substrate W conveyed by the conveyance robot Rb2. The process module PM2 forms a cap layer on a surface of the processing target substrate W. The cap layer may be, for example, a SiN film, and prevent a dopant from escaping from the film due to annealing to be described later. In an exemplary embodiment, the process module PM2 may have the same configuration as the film forming device 10. In such an exemplary embodiment, the process module PM2 may supply a precursor gas of silicon, for example, BTBAS (bis-tertial-butyl amino silane), to the first region R1, and generate plasma of nitrogen gas (N₂ gas) or NH₃ gas in the second region R2.

The processing target substrate W provided with the cap layer by the process module PM2 is conveyed to the process module PM3 by the conveyance robot Rb2. The process module PM3 is an annealing device of an exemplary embodiment. As for the annealing device, a lamp annealing device using ordinary lamp-heating or a microwave annealing device using microwaves may be used. The process module PM3 performs an annealing processing on the processing target substrate W accommodated therein. As a result, the process module PM3 activates the film formed on the processing target substrate W and including the dopant. In an exemplary embodiment, the process module PM3 may heat the processing target substrate W for about one sec at a temperature of 1050° C. within a N₂ gas atmosphere. The heating time of the annealing processing, is considerably shorter than the time required for a heating processing used for conventional solid phase diffusion and is, for example, preferably 0.1 sec to 10 sec, and more preferably, 0.5 sec to 5 sec. Accordingly, excessive diffusion of the dopant may be suppressed. For example, the diffusion of the dopant in a longitudinal direction of a channel of a semiconductor/an LSI may be suppressed.

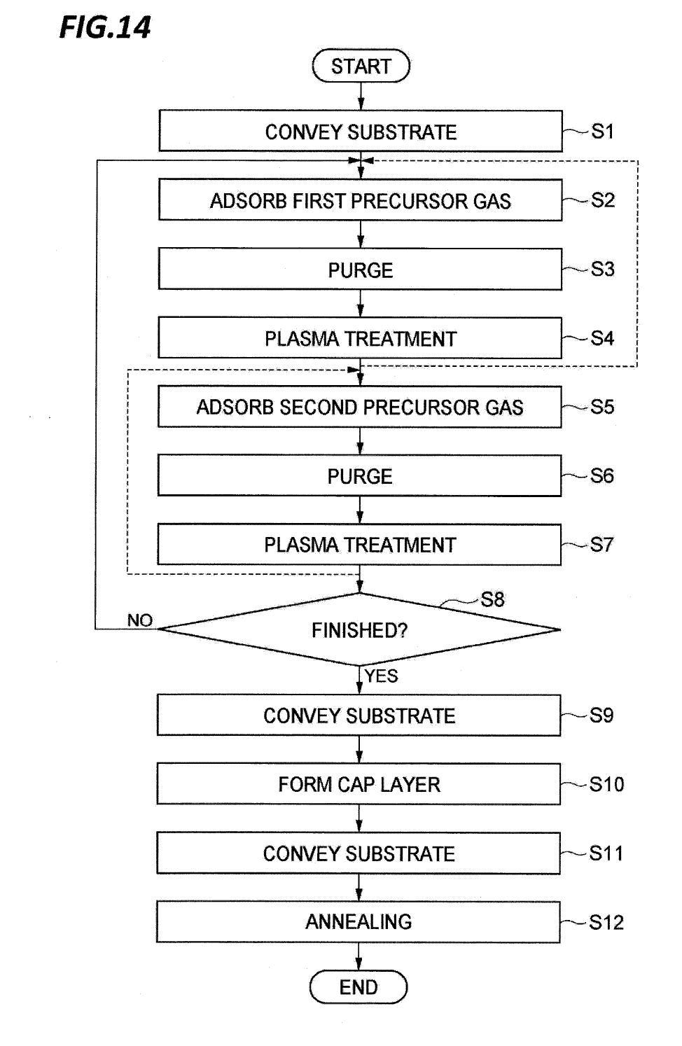

Hereinafter, an exemplary embodiment of a film forming method using the film forming system 100 will be described. FIG. 14 is a flowchart illustrating a film forming method according to an exemplary embodiment. In the film forming method illustrated in FIG. 14, first, at step S1, a processing target substrate W is conveyed to the process module PM1, that is, the film forming device 10. Then, in the film forming device 10, film formation including steps S2 to S8 is performed. In addition, at steps S2 to S8, the processing target substrate W is heated to 200° C. to 400° C. by the heater 26.

(First Precursor Gas Adsorption Step: Step S2)

In the film forming device 10, first, the processing target substrate W is sent to the first region R1 by the rotation of the mounting table 14. While step S2 is performed, the first precursor gas is supplied to the first region R1. Accordingly, at step S2, the first precursor gas is chemically adsorbed onto a surface of the processing target substrate W. In an exemplary embodiment, dichlorosilane (DCS) is supplied to the first region as the first precursor gas at a flow rate of 30 sccm.

(Purge Step: Step S3)

Subsequently, following the rotation of the mounting table 14, the processing target substrate W passes through an area under the injection port 20a. At step S3, the first precursor gas excessively adsorbed onto the processing target substrate W is removed by the inert gas injected from the injection port 20a. In an exemplary embodiment, the inert gas is Ar gas and its flow rate is 540 sccm.

(Plasma Treatment Step: Step S4)

Subsequently, following the rotation of the mounting table 14, the processing target substrate W reaches the second region R2. While step S4 is performed, a reaction gas is supplied to the second region R2 and microwaves as a plasma source are also supplied to the second region R2. In an exemplary embodiment, as for the reaction gas, hydrogen gas, i.e. H₂ gas is supplied to the second region R2 at a flow rate of 60 sccm, and microwaves having a frequency of 2.45 GHz and a power of 3 kW are also supplied to the second region. As a result, plasma of the hydrogen gas is generated in the second region R2. In the second region R2, chlorine is extracted from the first precursor gas layer adsorbed onto the processing target substrate W by the reduction reaction by hydrogen ions in the plasma. As a result, a silicon atom layer is formed on the processing target substrate W. In addition, the pressure of the second region R2 is preferably 1 Torr (133.3 Pa) or higher. For example, the pressure of the second region R2 is preferably 1 Torr (133.3 Pa) to 50 Torr (6666 Pa), more preferably 1 Torr (133.3 Pa) to 10 Torr (1333 Pa). Under the high pressure, because a lot of hydrogen ions are generated, the reduction action for extracting the chlorine from the first precursor gas layer may be exhibited more properly.

(Second Precursor Gas Adsorption Step: Step S5)

In the present method, after steps S2 to S4 are repeated one or more times, step S5 is performed. At step S5, following the rotation of the mounting table 14, the processing target substrate W reaches the first region R1, and at this time, the second precursor gas is supplied to the first region R1, and the second precursor gas is chemically adsorbed onto the surface of the processing target substrate W. In an exemplary embodiment, the second precursor gas is AsClH₂ gas, and is supplied to the first region R1 at a flow rate of 30 sccm.

(Purge Step: Step S6)

Subsequently, following the mounting table 14, the processing target substrate W is passes through the area below the injection port 20a. At step S6, the second precursor gas excessively adsorbed onto the processing target substrate W is removed by the inert gas injected from the injection port 20a. In an exemplary embodiment, the inert gas is Ar gas, and its flow rate is 540 sccm.

(Plasma Treatment Step: Step S7)

Subsequently, following the rotation of the mounting table 14, the processing target substrate W reaches the second region R2. At step S7, a plasma treatment is performed on the processing target substrate W as at step S4. In an exemplary embodiment, hydrogen gas, i.e. H₂ gas is supplied to the second region R2 as the reaction gas at a flow rate of 60 sccm, and microwaves having a frequency of 2.45 GHz and a power of 3 kW are also supplied to the second region. As a result, in the second region R2 plasma of the hydrogen gas is generated. In the second region R2, chlorine is extracted from the second precursor gas layer adsorbed onto the processing target substrate W by the reduction reaction by hydrogen ions in the plasma. As a result, a dopant material layer is formed on the processing target substrate W. In the present exemplary embodiment, an As layer is formed. In addition, the pressure of the second region R2 at step S7 is preferably 1 Torr or higher like the pressure at step S4.

In the present method, after repeating steps S5 to S7 one or more times, at step S8, it is determined whether a series of steps (steps S2 to S7) are finished or not. In an exemplary embodiment, the number of times of repeating steps S1 to S7 is set in advance, and when the number of times of repeating steps S1 to S7 exceeds the predetermined number of times, the present method proceeds to step S9.

At step S9, the processing target substrate W is conveyed to the process module PM2. Then, at the next step S10, a cap layer is formed on the surface of the processing target substrate W in the process module PM2. In an exemplary embodiment, the cap layer may be formed by supplying BTBAS to the first region R1 and generating plasma of NH₃ gas in the second region R2 in the process module PM2 which is a separate film forming device having the same configuration as the film forming device 10.

At the next step S11, the processing target substrate W is conveyed from the process module PM2 to the process module PM3. In the process module PM3, an annealing processing is performed on the processing target substrate W. As a result, the film formed on the processing target substrate W and containing a dopant is activated. In an exemplary embodiment, the processing target substrate W is heated for about 1 sec at a temperature of 1050° C. within a N₂ gas atmosphere. The heating is performed, for example, preferably for 0.1 sec to 10 sec, more preferably 0.5 sec to 5 sec. In the present method, the film containing the dopant may be activated by the annealing of such a short time, and excessive diffusion of the dopant may be suppressed. For example, it is possible to suppress the diffusion of the dopant in the longitudinal direction of a channel of a semiconductor device/LSI. In addition, as described above, since the film containing the dopant is formed on the surface of the processing target substrate W prior to the annealing processing, evaporation of the dopant may be suppressed.

Because the film forming method described in the foregoing is a film forming method based on an ALD method, a film containing a dopant may be formed to follow a three-dimensionally structured surface with a high uniformity. In addition, the concentration of the dopant in the film may be adjusted by adjusting a ratio of the number of times of performing step S2 in which the first precursor gas is adsorbed onto a processing target substrate W and the number of times of performing step S5 in which the second precursor gas is adsorbed onto the processing target substrate W.

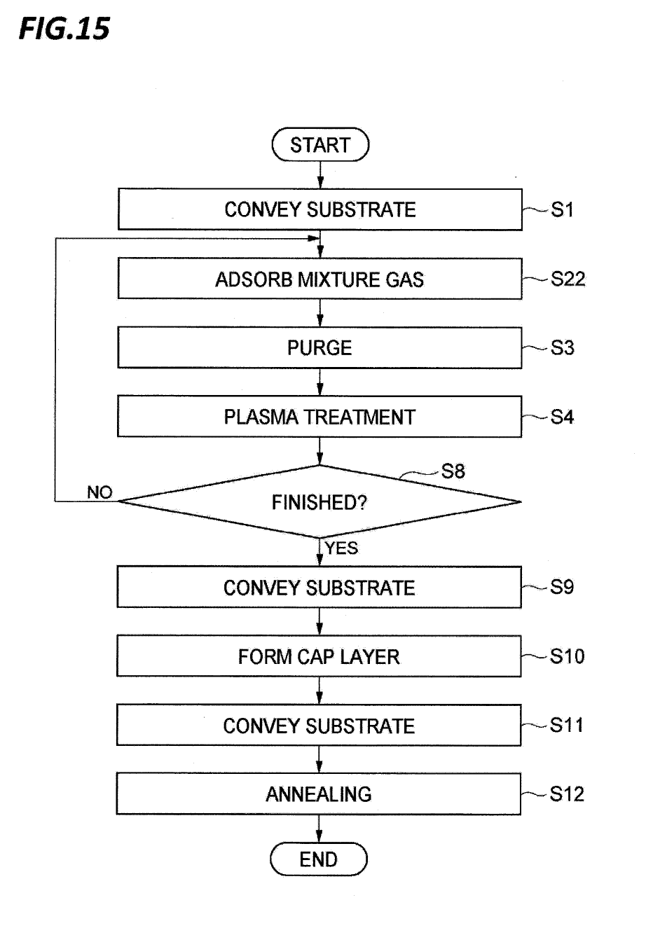

Next, another exemplary embodiment of a film forming method using the film forming system 100 will be described with reference to FIG. 15. FIG. 15 is a flowchart illustrating a film forming method according to another exemplary embodiment. The film forming method illustrated in FIG. 15 is different from the film forming method illustrated in FIG. 15 in that, at step S22, a mixture gas of the first precursor gas and the second precursor gas is supplied to the first region R1 so that the mixture gas is adsorbed onto a processing target substrate W. In the film forming method illustrated in FIG. 15, the concentration of the dopant in the film formed on the processing target substrate W may be adjusted by adjusting a ratio of the flow rate of the first precursor gas and the flow rate of the second precursor gas in the mixture gas.

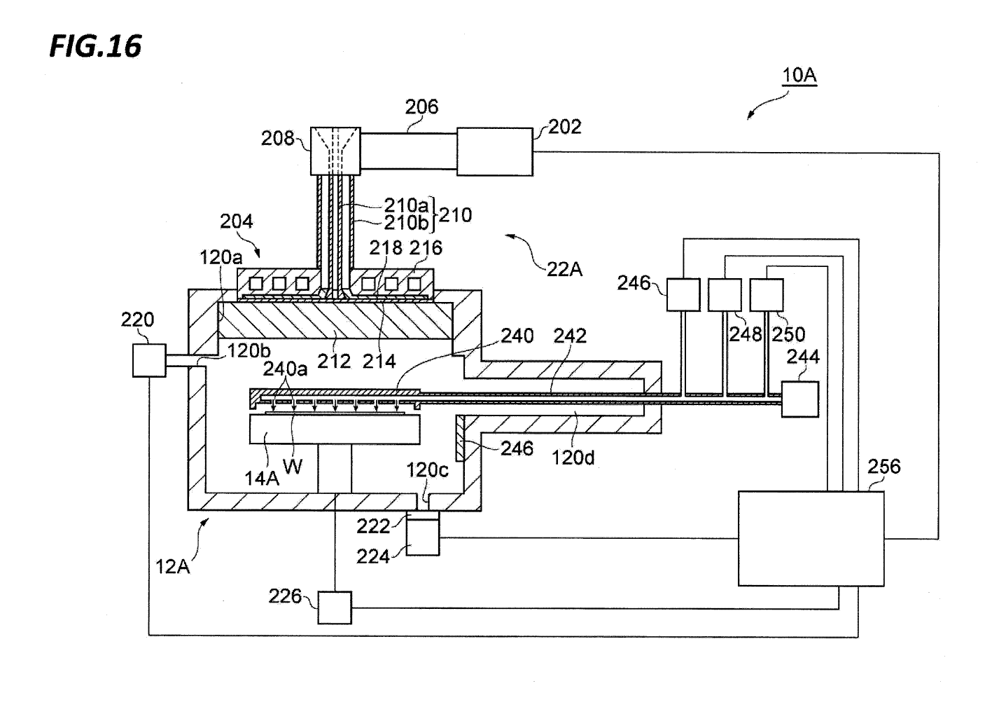

In the foregoing, various exemplary embodiments have been described. However, various modified embodiments may be made without being limited to the above-described exemplary embodiments. For example, the above-described film forming device 10 is a semi-batch type film forming device. However, as for a film forming device for forming a film containing a dopant, the film forming device illustrated in FIG. 16 may also be used.

The film forming device 10A illustrated in FIG. 16 is a single wafer type film forming device which includes a processing head configured to supply a precursor gas. Specifically, the film forming device 10A is provided with a processing vessel 12A, a mounting table 14A configured to hold a processing target substrate W within the processing vessel 12A, and a plasma generation section 22A configured to generate plasma of a reaction gas within the processing vessel 12A.

The plasma generation section 22A includes a microwave generator 202 configured to generate microwaves for plasma excitation, and a radial line slot antenna 204 configured to introduce the microwaves into the processing vessel 12A. The microwave generator 202 is connected to a mode converter 208 configured to convert the mode of the microwaves through a waveguide 206. The mode converter 208 is connected to a radial line slot antenna 204 through a coaxial waveguide 210 including an inner waveguide 210a and an outer waveguide 210b. The microwaves generated by the microwave generator 202 are mode-converted in the mode converter 208 and then reach the radial line slot antenna 204. The frequency of the microwaves generated by the microwave generator 202 is, for example, 2.45 GHz.

The radial line slot antenna 204 includes a dielectric window 212 configured to block an aperture 120a formed in the processing vessel 12A, a slot plate 214 installed just above the dielectric window 34, a cooling jacket 216 installed above the slot plate 214, and a dielectric plate 218 disposed between the slot plate 214 and the cooling jacket 216. The slot plate 214 has substantially a disc shape. In the slot plate 214, a plurality of slot pairs, each of which includes two slots extending in orthogonal or crossing directions, is provided to be arranged in a radial direction and a circumferential direction of the slot plate 214.

The dielectric window 212 is installed to face the processing target substrate W. The inner waveguide 210a is connected to the center of the slot plate 214, and the outer waveguide 210b is connected to the cooling jacket 216. The cooling jacket 216 also functions as a waveguide. Thus, the microwaves propagating between the inner waveguide 210a and the outer waveguide 210b penetrate the dielectric plate 218 and the dielectric window 212 while being reflected between the slot plate 214 and the cooling jacket 216, thereby reaching the inside of the processing vessel 12A.

A supply port 120b of a reaction gas is formed in a side wall of the processing vessel 12A. A supply source 220 of the reaction gas is connected to the supply port 120b. As for the reaction gas, hydrogen gas may be used as described above. In the film forming device 10A, when the microwaves are irradiated to the reaction gas, plasma of the reaction gas is generated.

In the bottom portion of the processing vessel 12A, an exhaust port 120c is formed so as to exhaust the gas within the processing vessel 12A. A vacuum pump 224 is connected to the exhaust port 120c through a pressure regulator 222. A temperature regulator 226 is connected to the mounting table 14A so as to regulate the temperature of the mounting table 14A.

The film forming device 10A further includes a head portion 240 which is formed with injection ports 240a configured to inject the first precursor gas, the second precursor gas, and a purge gas. The head portion 240 is connected to a driving device 244 through a support 242. The driving device 244 is disposed outside of the processing vessel 12A. By the driving device 244, the head portion 240 may be moved between a position where the head portion 240 faces the mounting table 14A, and a retreat space 120d defined within the processing vessel 12A. In addition, when the head portion 240 is positioned in the retreat space 120d, a shutter 246 is moved to isolate the retreat space 120d.

The support 242 defines a gas supply path configured to supply a gas to the injection ports 240a, and a first precursor gas supply source 246, a second precursor gas supply source 248, and a purge gas supply source 250 are connected to the gas supply path of the support 242. All the gas supply sources 246, 248 and 250 are flow rate-controllable gas supply sources. Accordingly, from the head portion 240, the first precursor gas, the second precursor gas, and the purge gas may be selectively injected to the processing target substrate W.

In addition, the film forming device 10A is provided with a control unit 256. The control unit 256 is connected to the microwave generator 202, the vacuum pump 224, the temperature regulator 226, the driving device 244, and the supply sources 220, 246, 248, and 250. Thus, the control unit 256 may control each of the power of microwaves, the pressure within the processing vessel 12A, the temperature of the mounting table 14A, the movement of the head portion 240, and the gas flow rate and supply timing of each of the reaction gas, the first precursor gas, the second precursor gas, and the purge gas.

A small space, to which the first precursor gas, the second precursor gas, and the purge gas are supplied, is defined between the head portion 240 of the film forming device 10A and the mounting table 14A. In addition, it is possible to always keep generated plasma of the reaction gas in the processing vessel 12A. According to such a film forming device, the space configured to supply the precursor gas may be reduced in size, and because it is possible to always keep the generated plasma in the processing vessel 12A, a high throughput may be realized.

In another exemplary embodiment, a single wafer type film forming device which does not include the head portion 240 may be used. In the single wafer type film forming device, the gases supplied to the processing vessel are switched in the order of the first precursor gas, the purge gas, the reaction gas, the second precursor gas, the purge gas, the reaction gas, and the purge gas so that a film containing a dopant as described above may be formed.

In addition, the above-described process module PM3 performs annealing by heating a processing target substrate W. However, as for a process module for activating a film containing a dopant, a process module configured to irradiate microwaves to the processing target substrate W may be used.

In addition, as for the first precursor gas, a precursor gas of, for example, silane, disilane, methyl silane, dimethyl silane, chlorosilane (SiH₃Cl), or trichlorosilane (SiHCl₃) may be used, instead of DCS. In addition, as for the second precursor gas, a mixture gas of B₂H₆ and He, BF₃ gas, AsH₃ gas, AsH₄ gas, or PH₃ gas may be used. Further, when the precursor gas contains carbon, the reaction gas may include oxygen gas in addition to hydrogen gas.

In addition, although the above-described exemplary embodiments are mainly related to formation of a film containing silicon and a dopant, the film may contain other semiconductor materials or compound semiconductor materials such as III-V group compound semiconductors, instead of silicon.

A doping processing method of another exemplary embodiment is a method of doping a desired dopant to a processing target substrate. The method includes: (a) a step of supplying a first precursor gas of a semiconductor material into a chamber (processing vessel), in which a processing target substrate is disposed, so that the first precursor gas is adsorbed onto the processing target substrate, (b) a step of supplying a second precursor gas of the dopant material into the processing vessel so that the second precursor gas is adsorbed onto the processing target substrate, and (c) a step of performing a plasma treatment in an atmosphere gas so as to dope an atom adsorption layer adsorbed onto the processing target substrate within the processing vessel. In an exemplary embodiment, the plasma may be excited by microwaves.

This doping processing method causes the first precursor gas and the second precursor gas to be adsorbed onto the processing target substrate by the atomic layer deposition (ALD) method, and then dopes the dopant atom adsorption layer adsorbed onto the processing target substrate by the plasma treatment. Thus, according to the present method, it is possible to form a film containing a dopant on a three-dimensionally structured surface, that is, a plurality of differently oriented surfaces uniformly and conformally. The term “conformally” is used to express a situation in which doping is uniformly performed without unevenness in concentration on a three-dimensionally structured surface.

### DESCRIPTION OF SYMBOLS

10: film forming device, 12: processing vessel, 14: mounting table, 16: gas supply section (first and second precursor gas supply section), 20: gas supply section (purge gas supply section), 22: plasma generation section, 60: control unit, 100: film forming system, PM1: process module (film forming device), PM2: process module (separate film forming device), PM3: process module (annealing device), W: processing target substrate

1. A film forming method comprising:
a step of supplying a first precursor gas of a semiconductor material into a processing vessel in which a processing target substrate is disposed so that the first precursor gas is adsorbed onto the processing target substrate;
a step of supplying a second precursor gas of a dopant material into the processing vessel so that the second precursor gas is adsorbed onto the processing target substrate; and
a step of generating plasma of a reaction gas within the processing vessel so that a plasma treatment is performed so as to modify a layer adsorbed onto the processing target substrate.

2. The film forming method of claim 1, wherein the step of supplying the first precursor gas and the step of supplying the second precursor gas are separately performed.

3. The film forming method of claim 2, wherein the step of generating the plasma includes a step of performing a first plasma treatment and a step of performing a second plasma treatment,
during the step of performing the first plasma treatment, the plasma treatment is performed by the plasma of the reaction gas on a layer adsorbed onto the processing target substrate by the step of supplying the first precursor gas, and
during the step of performing the second plasma treatment, the plasma treatment is performed on a layer adsorbed onto the processing target substrate by the step of supplying the second precursor gas.

4. The film forming method of claim 3, wherein each of the first precursor gas and the second precursor gas further includes hydrogen atoms and/or chlorine atoms, and
during the step of performing the first plasma treatment and the step of performing the second plasma treatment, plasma of hydrogen gas which is the reaction gas is excited.

5. The film forming method of claim 1, wherein the step of supplying the first precursor gas and the step of supplying the second precursor gas are performed simultaneously so that a mixture gas of the first precursor gas and the second precursor gas is adsorbed onto the processing target substrate.

6. The film forming method of claim 5, wherein each of the first precursor gas and the second precursor gas further includes hydrogen atoms and/or chlorine atoms, and
during the step of performing the first plasma treatment and the step of performing the second plasma treatment, plasma of hydrogen gas which is the reaction gas is excited.

7. The film forming method of claim 1, wherein during the step of performing the plasma treatment, the plasma is excited by microwaves.

8. The film forming method of claim 7, wherein during the step of performing the plasma treatment, a pressure within the processing vessel is set to be in a range of 133.3 Pa to 6666 Pa.

9. The film forming method of claim 1, further comprising a step of annealing the processing target substrate after a series of steps including the step in which the first precursor gas is adsorbed, the step in which the second precursor gas is adsorbed, and the step of generating the plasma are repeated one or more times.

10. The film forming method of claim 9, wherein the step of annealing the processing target substrate is performed for 0.1 sec to 10 sec.

11. The film forming method of claim 9, further comprising a step of forming a cap layer on a surface of the film formed on the processing target substrate prior to the step of annealing the processing target substrate.

12. A film forming device comprising:
a processing vessel in which a processing target substrate is disposed;
a supply section configured to supply a first precursor gas of a semiconductor material, and a second precursor gas of a dopant material into the processing vessel so that the first precursor gas and the second precursor gas are adsorbed onto the processing target substrate; and
a plasma generation section configured to generate plasma of a reaction gas in the processing vessel so as to modify a layer adsorbed onto the processing target substrate by a plasma treatment.

13. The film forming device of claim 12, further comprising a control unit configured to control the supply section and the plasma generation section.

14. The film forming device of claim 13, wherein the control unit controls the supply section to supply the first precursor gas into the processing vessel,
the control unit controls the plasma generation section to generate plasma of the reaction gas so as to perform a plasma treatment on a layer adsorbed onto the processing target substrate by supplying the first precursor gas,
the control unit controls the supply section to supply the second precursor gas into the processing vessel, and
the control unit controls the plasma generation section to generate plasma of the reaction gas so as to perform a plasma treatment on a layer adsorbed onto the processing target substrate by supplying the second gas.

15. The film forming device of claim 13, wherein the supply section supplies a mixture gas of the first precursor gas and the second precursor gas into the processing vessel, and
the control unit controls the supply section to supply the mixture gas into the processing vessel, and controls the plasma generation section to generate the plasma of the reaction gas so as to perform the plasma treatment on the layer adsorbed onto the processing target substrate by supplying the mixture gas.

16. The film forming device of claim 12, wherein each of the first gas and the second gas further includes hydrogen atoms and/or chlorine atoms, and
the plasma generation section generates plasma of hydrogen gas which is the reaction gas.

17. The film forming device of claim 12, wherein the plasma generation section excites the plasma of the reaction gas by microwaves.

18. The film forming device of claim 12, wherein the film forming device is a film forming device of a doping system using ALD film formation.

19. A film forming system comprising:
the film forming device claimed in claim 12; and
an annealing device configured to receive the processing target substrate processed by the film forming device and anneal the processing target substrate.

20. The film forming system of claim 19, further comprising a separate film forming device connected with the film forming device through a vacuum conveyance system, the separate film forming device being configured to receive the processing target substrate from the film forming device and form a cap layer on a surface of the processing target substrate,
wherein the annealing device is connected to the separate film forming device so as to anneal the processing target substrate conveyed from the separate film forming device.
